(19) United States
(12) Patent Application Publication
(10) Pub. No.: US 2008/0176374 A1
(43) Pub. Date: Jul. 24, 2008

(54) METHODS OF FORMING SEMICONDUCTOR DEVICES USING SELF-ALIGNED METAL SHUNTS

(75) Inventors: Yeol Jon, Gyeonggi-do (KR); Eun-Kuk Chung, Seoul (KR); Joon Kim, Seoul (KR); Jin-Hong Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/018,469

(22) Filed: Jan. 23, 2008

(30) Foreign Application Priority Data
Jan. 23, 2007 (KR) 10-2007-07134

(51) Int. Cl. H01L 21/336; H01L 21/768

(52) U.S. Cl. 438/301; 438/672; 257/E21.409; 257/E21.585

(57) ABSTRACT

A method of fabricating a semiconductor device using a self-aligned metal shunt process is disclosed. The method can include sequentially forming a lower conductive pattern and a sacrificial pattern on a semiconductor substrate. An interlayer dielectric layer is formed to cover the sacrificial pattern. The interlayer dielectric layer is patterned to form a preliminary trench that exposes the top surface of the sacrificial pattern. The exposed sacrificial pattern is removed to form a trench that expose the top surface of the lower conductive pattern. An upper conductive pattern is formed to fill the trench.

### CROSS-REFERENCE TO RELATED APPLICATION

This application relies for priority upon Korean Patent Application No. 10-2007-0007134, filed on Jan. 23, 2007, the contents of which are herein incorporated by reference in their entirety.

### FIELD OF THE INVENTION

The present invention relates to methods of fabricating semiconductor devices.

### BACKGROUND

A variety of techniques for increasing the operating speed of semiconductor devices have been proposed. For example, a method of forming interconnection lines with a metal of a low resistivity has been proposed in order to inhibit speed delay due to interconnection resistance. Especially, in the case of a static random access memory (SRAM), a method of forming word lines with tungsten has been proposed to reduce the resistance of the word lines. As is known, it is necessary to reduce the equivalent thickness of oxide (ETOX) in order to meet the demand for a reduction in the linewidth of patterns and increase the operating speed of semiconductor devices. However, since the reduction of the ETOX may bring about a pitting problem and/or an undercut problem, a tungsten shunt technique of additionally forming a tungsten layer on a gate pattern formed of polycrystalline silicon (poly-Si) has been proposed. Here, the pitting problem occurs when a semiconductor substrate adjacent to a gate pattern is physically damaged during a gate patterning process, and the undercut problem is caused by laterally recessing a gate insulating layer during a cleaning process performed after the gate patterning process.

FIGS. 1 and 2 are cross-sectional views illustrating a conventional tungsten shunt process. Referring to FIG. 1, the conventional tungsten shunt process includes forming a gate insulating layer 12 on a semiconductor substrate 10, sequentially stacking a poly-Si pattern 13 and a hard mask pattern 14 on the gate insulating layer 12, and forming impurity regions 15 in the semiconductor substrate 10 on both sides of the poly-Si pattern 13. Referring to FIG. 2, the hard mask pattern 14 is removed, and an interlayer dielectric layer 17 is formed on the resultant structure from which the hard mask pattern 14 is removed. Thereafter, the interlayer dielectric layer 17 is patterned to form a gate trench 20 exposing the top surface of the poly-Si pattern 13. Subsequently, a tungsten layer is deposited to fill the gate trench 20 so that the gate structure is completed.

According to the above-described method, the gate trench 20 may be over-etched to completely expose the top surface of the poly-Si pattern 13. However, due to a variation in the thickness of the interlayer dielectric layer 17 and misalignment in the process of forming the gate trench 20, the top surface of the semiconductor substrate 10 may be exposed during the over-etching of the gate trench 20. In this case, since the subsequently formed tungsten layer is connected to both the poly-Si pattern 13 (i.e., a gate electrode) and the semiconductor substrate 10 (i.e., source/drain electrodes), a failure, such as a short, may occur.

### SUMMARY

According to an aspect of the present invention, there is provided a method of fabricating a semiconductor device. The method can include sequentially forming a lower conductive pattern and a sacrificial pattern on a semiconductor substrate. An interlayer dielectric layer is formed to cover the sacrificial pattern. The interlayer dielectric layer is patterned to form a preliminary trench that exposes the top surface of the sacrificial pattern. The exposed sacrificial pattern is removed to form a trench that expose the top surface of the lower conductive pattern. An upper conductive pattern is formed to fill the trench.

According to the present invention, the sacrificial pattern may be formed of at least one material having an etch selectivity with respect to the lower conductive pattern and the interlayer dielectric layer, and the upper conductive pattern may be formed of a metal layer. For example, the lower conductive pattern may be formed of a polycrystalline silicon (poly-Si) layer, the sacrificial pattern may be formed of at least one of a silicon oxide layer, a silicon nitride layer, and a silicon oxynitride layer, and the upper conductive pattern may be formed of a tungsten layer.

The formation of the preliminary trench may include forming a mask pattern on the sacrificial pattern to expose the interlayer dielectric layer. The interlayer dielectric layer may be etched using the mask pattern as an etch mask, and the mask pattern may be removed. The etching of the interlayer dielectric layer may include etching the interlayer dielectric layer formed on the sacrificial pattern until the top surface of the sacrificial pattern is exposed.

The formation of the trench may include selectively removing the sacrificial pattern exposed by the preliminary trench using a wet etching process or a dry etching process.

The formation of the upper conductive pattern may include forming an upper conductive layer to fill the trench. The upper conductive layer may be etched back until the top surface of the interlayer dielectric layer is exposed. The etching back of the upper conductive layer may be performed using a chemical mechanical polishing (CMP) process. Also, the etching back of the upper conductive layer may be performed until the top surface of the interlayer dielectric layer becomes lower than the bottom surface of the preliminary trench.

In an embodiment of the present invention, before forming the lower conductive pattern, the method may further include forming a gate insulating layer interposed between the lower conductive pattern and the semiconductor substrate. Before forming the interlayer dielectric layer, the method may further include forming impurity regions for source and drain electrodes of a transistor in the semiconductor substrate on both sides of the lower conductive pattern. In this case, the lower conductive pattern and the upper conductive pattern may be used as a gate electrode of the transistor.

In an embodiment of the present invention, the upper conductive pattern may be formed to have an upper width greater than a lower width.

### BRIEF DESCRIPTION OF THE DRAWINGS

FIGS. 1 and 2 are cross-sectional views illustrating a conventional tungsten shunt process;

FIGS. 3 through 9 are cross-sectional views illustrating a method of fabricating a semiconductor device according to an embodiment of the present invention; and

FIGS. 10 and 11 are cross-sectional views illustrating a method of fabricating a semiconductor device according to another embodiment of the present invention.

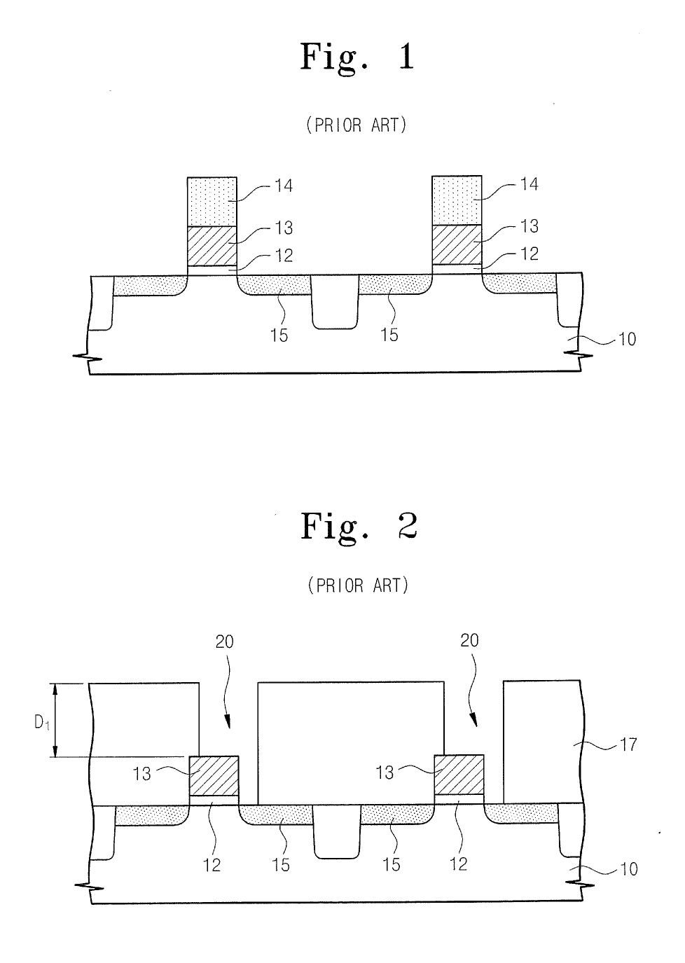

### DESCRIPTION OF EMBODIMENTS ACCORDING TO THE INVENTION

The present invention is described more fully hereinafter with reference to the accompanying drawings, in which embodiments of the invention are shown by way of example. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. Moreover, each embodiment described and illustrated herein includes its complementary conductivity type embodiment as well.

It will be understood that when an element is referred to as being “connected to,” “coupled to” or “responsive to” (and/or variants thereof) another element, it can be directly connected, coupled or responsive to the other element or intervening elements may be present. In contrast, when an element is referred to as being “directly connected to,” “directly coupled to” or “directly responsive to” (and/or variants thereof) another element, there are no intervening elements present. Like numbers refer to like elements throughout. As used herein, the term “and/or” includes any and all combinations of one or more of the associated listed items and may be abbreviated as “/”.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising” (and/or variants thereof), when used in this specification, specify the presence of stated features, integers, steps, operations, elements, and/or components, but do not preclude the presence or addition of one or more other features, integers, steps, operations, elements, components, and/or groups thereof. In contrast, the term “consisting of” (and/or variants thereof) when used in this specification, specifies the stated number of features, integers, steps, operations, elements, and/or components, and precludes additional features, integers, steps, operations, elements, and/or components.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

Furthermore, relative terms such as “below,” “beneath,” or “lower,” “above,” and “upper” may be used herein to describe one element's relationship to another element as illustrated in the accompanying drawings. It will be understood that relative terms are intended to encompass different orientations of the device in addition to the orientation depicted in the accompanying drawings. For example, if the device in the accompanying drawings is turned over, elements described as being on the “lower” side of other elements would then be oriented on “upper” sides of the other elements. Similarly, if the device in one of the figures is turned over, elements described as “below” or “beneath” other elements would then be oriented “above” the other elements. Therefore, the exemplary terms “below” and “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing.

It will also be understood that when a layer is referred to as being “on” another layer or substrate, it can be directly on the other layer or substrate, or intervening layers may also be present. In the drawings, the thicknesses of layers and regions are exaggerated for clarity.

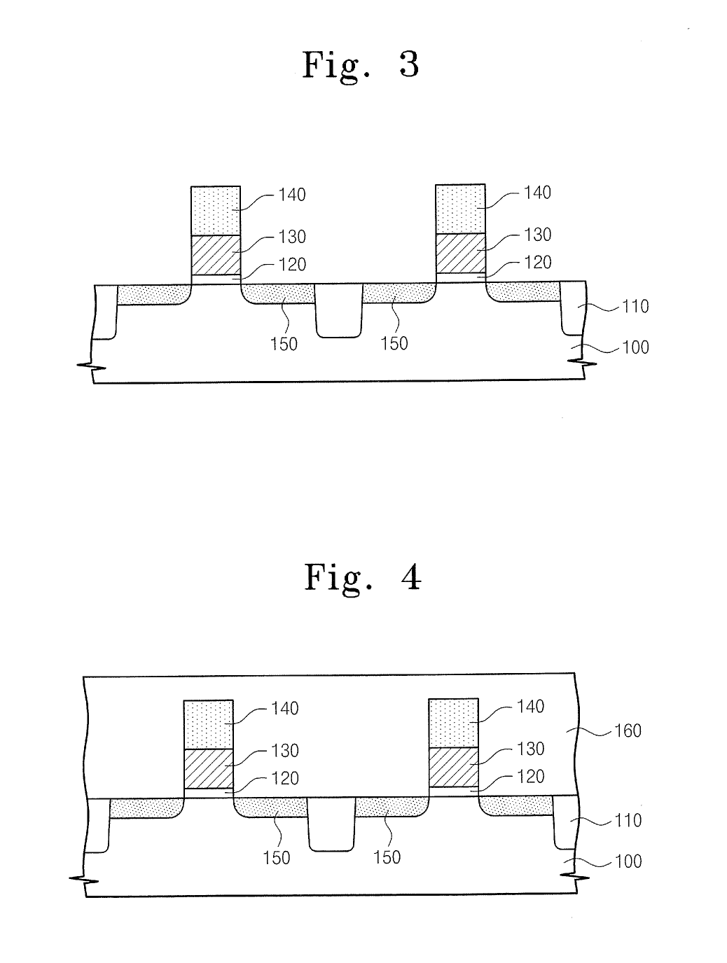

FIGS. 3 through 9 are cross-sectional views illustrating a method of fabricating a semiconductor device according to an embodiment of the present invention. Referring to FIG. 3, a device isolation pattern 110 is formed in a semiconductor substrate 100 to define active regions. A gate insulating layer 120 is formed on the active region. A lower conductive layer and a sacrificial layer are sequentially stacked on the resultant structure having the gate insulating layer 120 and sequentially patterned so that a lower conductive pattern 130 and a sacrificial pattern 140 are sequentially formed across the active region. Thereafter, an ion implantation process is performed using the sacrificial pattern 140 as a mask, thereby forming impurity regions 150 in the semiconductor substrate 100 on both sides of the lower conductive pattern 130.

According to the present invention, the gate insulating layer 120 may be one of a silicon oxide layer and a high-k dielectric layer. The lower conductive pattern 130 may be a poly-Si layer, and the sacrificial pattern 140 may be a material having an etch selectivity with respect to the lower conductive pattern 130. That is, the sacrificial pattern 140 may be formed of a material that is selectively etched and minimizes the etching of the lower conductive pattern 130 (hereinafter, the “etch selectivity” will be used in this sense).

Referring to FIG. 4, an interlayer dielectric layer 160 is formed on the resultant structure having the impurity regions 150. The interlayer dielectric layer 160 may be formed of at least one of a silicon oxide layer, a silicon nitride layer, a silicon oxynitride layer, and a low-k dielectric layer. In this case, the sacrificial pattern 140 may be formed of a material having an etch selectivity with respect to the interlayer dielectric layer 160. In an embodiment of the present invention, the sacrificial pattern 140 may be formed of at least one of a silicon oxide layer, a silicon nitride layer, and a silicon oxynitride layer, which has an etch selectivity with respect to the interlayer dielectric layer 160 and/or the lower conductive pattern 130.

The formation of the interlayer dielectric layer 160 may include planarizing the top surface of the interlayer dielectric layer 160. The planarization process may be performed using one of a chemical mechanical polishing (CMP) process and an etchback process. According to the present invention, the planarization process is performed until the interlayer dielectric layer 160 is left to a predetermined thickness D2 (refer to FIG. 3) on the sacrificial pattern 140.

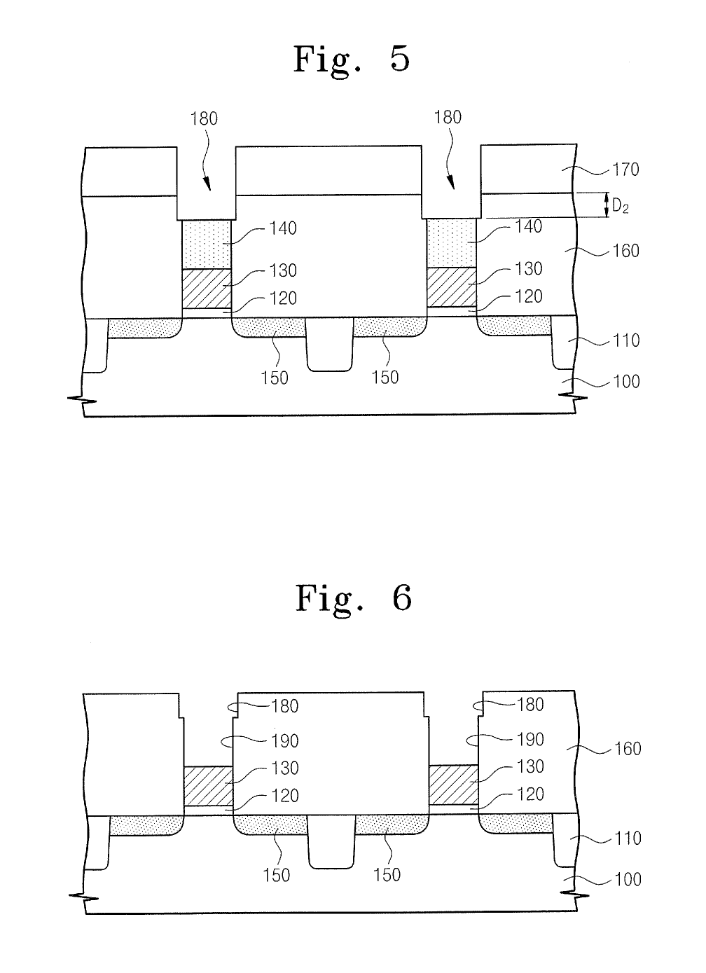

Referring to FIG. 5, a mask pattern 170 is formed over the lower conductive pattern 130 on the top surface of the interlayer dielectric layer 160. In an embodiment of the present invention, the mask pattern 170 may be a photoresist pattern formed using a photolithography process. The interlayer dielectric layer 160 is anisotropically etched using the mask pattern 170 as an etch mask so that a preliminary trench 180 is formed to expose a top surface of the sacrificial pattern 140.

According to the present invention, a depth D2 of the preliminary trench 180 (i.e., the etched depth of the etching process) is substantially the same as the thickness of the interlayer dielectric layer 160 remaining on the sacrificial pattern 140. The depth D2 of the preliminary trench 180 is smaller than the depth D1 (refer to FIG. 2) of the conventional gate trench 20 by the thickness of the sacrificial pattern 140. Owing to D2<D1, a variation in the etched amount of the interlayer dielectric layer 160 (i.e., a variation in the depth of the preliminary trench 180) can be reduced so that it is easy to stably control process parameters.

Furthermore, since the etching process for forming the preliminary trench 180 is stopped around the top surface of the sacrificial pattern 140, even if an over-etching process is performed, the impurity region 150 is not exposed by the preliminary trench 180 unlike in the conventional case.

Referring to FIG. 6, the mask pattern 170 is removed, and the sacrificial pattern 140 exposed by the preliminary trench 180 is removed. As a result, a trench 190 is formed in the interlayer dielectric layer 160 to expose the top surface of the lower conductive pattern 130. The trench 190 is used as a mold during a subsequent process for forming an upper conductive pattern.

The sacrificial pattern 140 is selectively removed using an etch recipe having an etch selectivity with respect to the lower conductive pattern 130 and/or the interlayer dielectric layer 160 to minimize the etching of the lower conductive pattern 130 and/or the interlayer dielectric layer 160. The removal of the sacrificial pattern 140 may be performed using a wet or dry etching process. In another embodiment of the present invention, the mask pattern 170 may be removed after removing the sacrificial pattern 140.

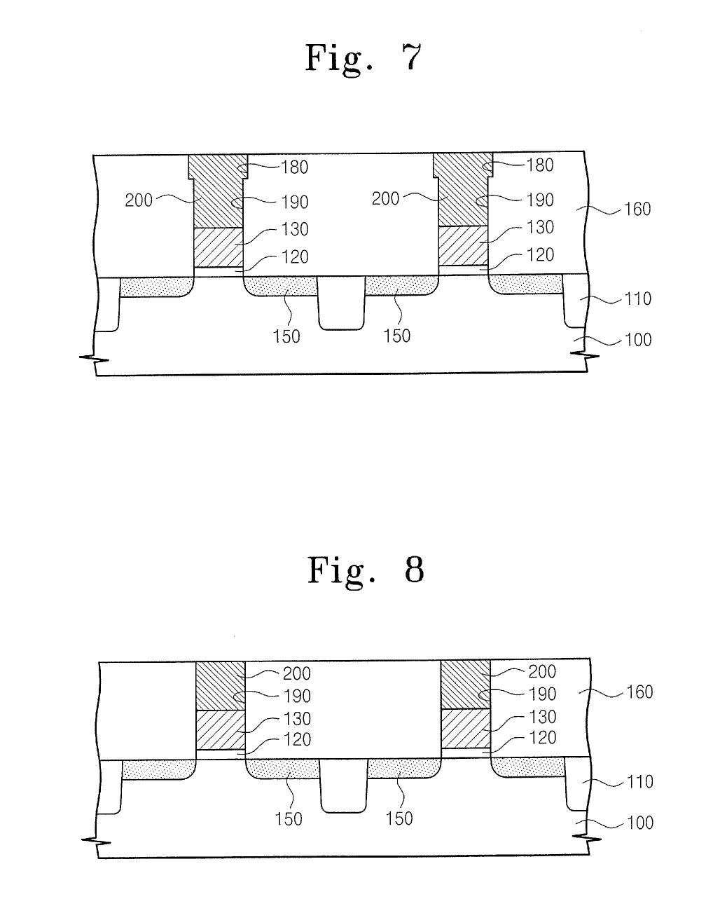

Referring to FIGS. 7 and 8, an upper conductive layer is formed to fill the trench 190 and planarized by etching until the top surface of the interlayer dielectric layer 160 is exposed. As a result, upper conductive patterns 200 are formed to fill the trench 190 and separated from one another by the interlayer dielectric layer 160. As explained above, since the sacrificial pattern 140 is aligned to the lower conductive pattern 130 and the trench 190 is a space formed by removing the sacrificial pattern 140, the upper conductive pattern 200 is self-aligned to the lower conductive pattern 130. The planarizing etching process may be performed using a known chemical mechanical polishing (CMP) process. According to the present invention, the upper conductive pattern 200 may be formed of a metal layer having a low resistivity, for example, a tungsten (W) layer.

In this case, the width of the preliminary trench 180 may be greater than that of the sacrificial pattern 140 or the trench 190. Also, the preliminary trench 180 may be misaligned from the sacrificial pattern 140. In this case, since the upper conductive pattern 200 becomes close to a contact plug 220 formed during a subsequent process, the likelihood of an electrical short increases. However, according to the present invention, the planarizing etching process may be performed such that the top surface of the interlayer dielectric layer 160 becomes lower than the bottom surface of the preliminary trench 180 as illustrated in FIG. 8.

In this case, since an upper region of the upper conductive pattern 200 of which position is determined by a misalignment or width expansion is removed, the problem of the electrical short can be solved. Furthermore, such an over-etching process for planarization allows the upper conductive pattern 200 to be self-aligned with the trench 190 formed by removing the sacrificial pattern 140, so that the conventional technical problem caused by the misalignment of the gate trench 20 can be overcome.

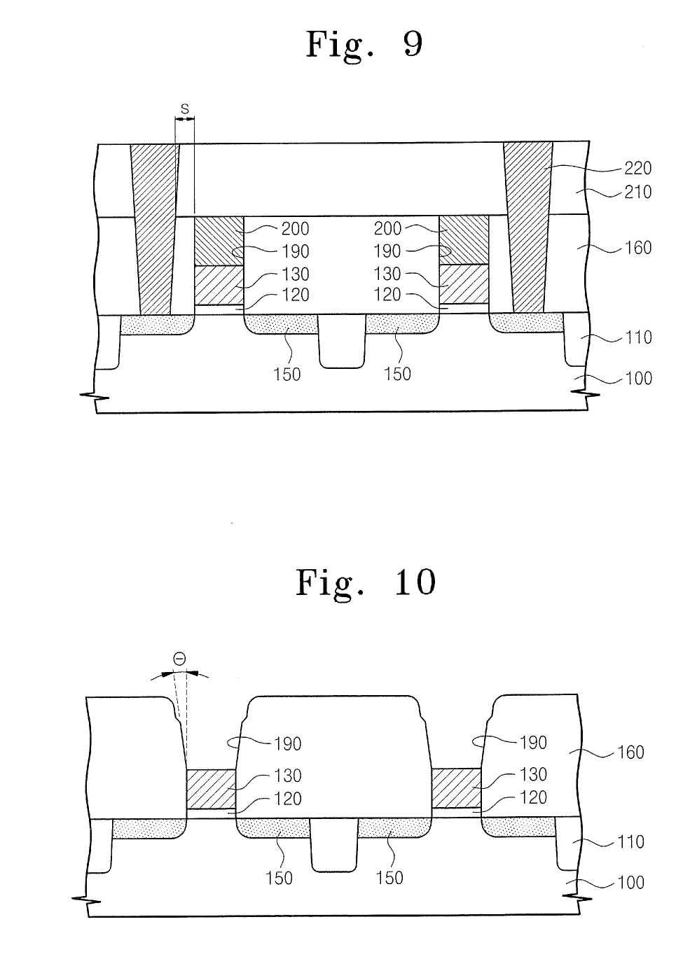

Referring to FIG. 9, an upper interlayer dielectric layer 210 is formed on the resultant structure having the upper conductive pattern 200 and patterned to form a contact hole exposing the impurity region 150. Thereafter, a contact plug 220 is formed to fill the contact hole.

In this case, the contact plug 220 is formed a predetermined space S apart from the lower and upper conductive patterns 130 and 200. As described above, since the upper conductive pattern 200 is self-aligned to the lower conductive pattern 130, the width of a gate pattern formed by the lower and upper conductive patterns 130 and 200 is substantially equal to each of the lower and upper conductive patterns 130 and 200. In comparison, according to the conventional art, since the position of the upper conductive pattern 200 is determined using a patterning process, the upper conductive pattern 200 may be misaligned from the lower conductive pattern 130. Thus, the width of a gate pattern according to the conventional art is equal to the sum of the linewidth of the upper conductive pattern 200 or the lower conductive pattern 130 and the length of a misalignment between the lower and upper conductive patterns 130 and 200, which is greater than the width of the gate pattern according to the present invention. Therefore, according to the present invention, a distance between the contact plug 220 and the gate pattern can be stably maintained at a reduced spacing.

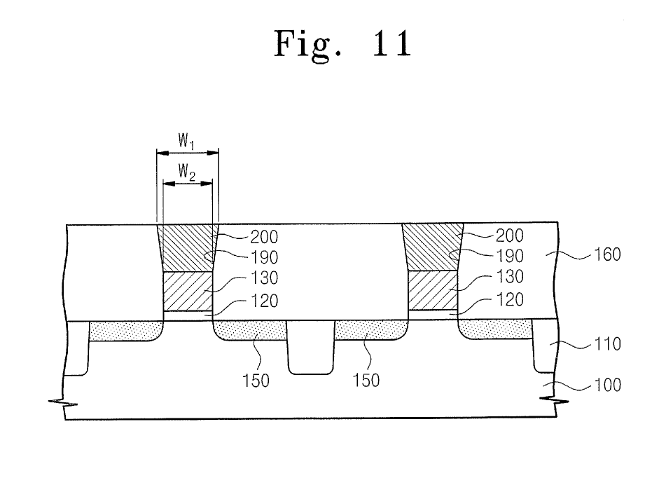

FIGS. 10 and 11 are cross-sectional views illustrating a method of fabricating a semiconductor device according to another embodiment of the present invention. Since the present embodiment is generally similar to the previous embodiment described with reference to FIGS. 3 through 9, the same description as in the previous embodiment will be omitted.

Referring to FIGS. 10 and 11, the removal of the sacrificial pattern 140 may include removing the sacrificial pattern 140 exposed by the preliminary trench 180 using a wet etching process. In this case, the exposed surface of the interlayer dielectric layer 160 may be etched by an etchant used for removing the sacrificial pattern 140. As a result, an inner sidewall of the trench 190 may be inclined as illustrated in FIG. 10. That is, as illustrated in FIG. 11, each of the trench 190 and the upper conductive pattern 200 may have an upper width greater than a lower width. The above-described profile of each of the trench 190 and the upper conductive pattern 200 is obtained because an upper region of the trench 190 is exposed to an etchant for a longer time than a lower region thereof during the removal of the sacrificial pattern 140, and distinguished from a profile obtained using a conventional patterning process. That is, when the conventional patterning process is used, a pattern has an upper width smaller than a lower width. Therefore, when the upper conductive pattern 200 is sufficiently apart from the contact plug 220, the method according to the present embodiment can be employed to increase the sectional area of the upper conductive pattern 200.

According to the present invention, a sacrificial pattern, which is used as an etch mask during the formation of a lower conductive pattern, is not removed directly after forming the lower conductive pattern but used to define a trench during a subsequent process of forming an upper conductive pattern. That is, the upper conductive pattern is formed using, as a mold, the trench formed by removing the sacrificial pattern. Thus, the upper conductive pattern may be shunted to the lower conductive pattern without causing a short due to a misalignment in a photolithography process and a variation in the thickness of an interlayer dielectric layer.

Furthermore, the removal of the sacrificial pattern includes patterning the interlayer dielectric layer covering the sacrificial pattern to expose the top surface of the sacrificial pattern and selectively removing the exposed sacrificial pattern. In this case, since only the interlayer dielectric layer remaining on the sacrificial pattern is etched during the patterning process for exposing the sacrificial pattern, the occurrence of a short due to the conventional over-etching process can be prevented.

It will be apparent to those skilled in the art that various modifications and variations can be made in the present invention. Thus, it is intended that the present invention covers the modifications and variations of this invention provided they come within the scope of the appended claims and their equivalents.

What is claimed:

1. A method of fabricating a semiconductor device, comprising:
sequentially forming a lower conductive pattern and a sacrificial pattern on a semiconductor substrate;
forming an interlayer dielectric layer to cover the sacrificial pattern;
patterning the interlayer dielectric layer to form a preliminary trench exposing the top surface of the sacrificial pattern;
removing the exposed sacrificial pattern to form a trench exposing the top surface of the lower conductive pattern; and
forming an upper conductive pattern to fill the trench.

2. The method according to claim 1, wherein the sacrificial pattern comprises at least one material having an etch selectivity with respect to the lower conductive pattern and the interlayer dielectric layer,
and the upper conductive pattern comprises a metal layer.

3. The method according to claim 1, wherein the lower conductive pattern comprises a polycrystalline silicon (poly-Si) layer,
the sacrificial pattern comprises a silicon oxide layer, a silicon nitride layer, and/or a silicon oxynitride layer,
and the upper conductive pattern comprises a tungsten layer.

4. The method according to claim 1, wherein forming the preliminary trench comprises:
forming a mask pattern on the sacrificial pattern to expose the interlayer dielectric layer;
etching the interlayer dielectric layer using the mask pattern as an etch mask; and
removing the mask pattern,
wherein etching the interlayer dielectric layer comprises etching the interlayer dielectric layer formed on the sacrificial pattern until the top surface of the sacrificial pattern is exposed.

5. The method according to claim 1, wherein forming the trench comprises selectively removing the sacrificial pattern exposed by the preliminary trench using one of a wet etching process and a dry etching process.

6. The method according to claim 1, wherein forming the upper conductive pattern comprises:
forming an upper conductive layer to fill the trench; and
etching back the upper conductive layer until the top surface of the interlayer dielectric layer is exposed.

7. The method according to claim 5, wherein etching back the upper conductive layer is performed using a chemical mechanical polishing (CMP) process.

8. The method according to claim 6, wherein etching back the upper conductive layer is performed until the top surface of the interlayer dielectric layer becomes lower than the bottom surface of the preliminary trench.

9. The method according to claim 1, before forming the lower conductive pattern, further comprising forming a gate insulating layer interposed between the lower conductive pattern and the semiconductor substrate.

10. The method according to claim 9, before forming the interlayer dielectric layer, further comprising forming impurity regions for source and drain electrodes of a transistor in the semiconductor substrate on both sides of the lower conductive pattern,
wherein the lower conductive pattern and the upper conductive pattern are used as a gate electrode of the transistor.

11. The method according to claim 1, wherein the upper conductive pattern is formed to have an upper width greater than a lower width.

12. A method of forming a conductive contact to a gate structure comprising:
maintaining a sacrificial layer to cover an underlying gate layer included in a gate structure until after etching an interlayer dielectric layer above the sacrificial layer to expose the sacrificial layer; and then removing the sacrificial layer to expose the underlying gate layer.

13. A method according to claim 12 further comprising:
forming the interlayer dielectric layer to cover the sacrificial layer.

14. A method of forming a conductive contact to a gate structure comprising:
selectively etching a sacrificial layer from a trench defined by an interlayer dielectric layer to expose a conductive layer included in a gate structure in the trench beneath the sacrificial layer while avoiding etching the interlayer dielectric layer.
